(19) United States
(12) Patent Application Publication
(10) Pub. No.: US 2015/0042409 A1
(43) Pub. Date: Feb. 12, 2015

(54) SYSTEM FOR CONTINUOUSLY OSCILLATING A CANTILEVERED BEAM

(71) Applicant: Earl J. Brown, Henderson, TX (US)

(72) Inventor: Earl J. Brown, Henderson, TX (US)

(21) Appl. No.: 14/451,587

(22) Filed: Aug. 5, 2014

Related U.S. Application Data
(60) Provisional application No. 61/862,662, filed on Aug. 6, 2013.

(51) Int. Cl. H03B 5/30

(52) U.S. Cl. CPC H03B 5/30; H03B 2200/003
USPC 331/156

(57) ABSTRACT

A continuously oscillating cantilevered beam having a velocity transducer that produces a preferably voltage signal as a function of the beam's velocity. An amplifier receives the signal and amplifies accordingly to produce an amplified signal that varies as a function of the beam's velocity. The amplified signal powers an electromagnet that is disposed in close proximity to a magnet on the beam. The resulting apparatus is a system that is driven cyclically by a force that is essentially generated in proportion to, and then amplified, the velocity of the beam itself. This ensures that the timing of applying the driving force is precisely synchronized with the movement of the beam.

### CROSS-REFERENCES TO RELATED APPLICATIONS

This application claims the benefit of U.S. Provisional Application No. 61/862,662 filed Aug. 6, 2013. This prior application is hereby incorporated by reference.

### STATEMENT REGARDING FEDERALLY-SPONSORED RESEARCH AND DEVELOPMENT

(Not Applicable)

### THE NAMES OF THE PARTIES TO A JOINT RESEARCH AGREEMENT

(Not Applicable)

### REFERENCE TO AN APPENDIX

(Not Applicable)

### BACKGROUND OF THE INVENTION

The invention relates broadly to reciprocating and/or oscillating devices, and more particularly to an efficient oscillating device and method that can be used for various purposes.

A typical cantilevered beam is illustrated in FIG. 1. A cantilevered beam is an elongated body that is held firmly at one end with the beam's opposite end free. The beam has a width, b; a length, l; and a thickness, h. When at rest, the beam is in a neutral position with no deformation of the beam. Cantilevered beams can be elastically deformed from the neutral position, such as by applying a force to the free end to move it in one direction, thereby deflecting the free end and bending the portion of the beam between the free end and the held end. When the beam is deflected under elastic deformation, the forces between the molecules making up the beam are strained, resulting in a net force tending to restore the beam to its original, undeflected position. This net force can be described as potential energy stored in the deflected beam. This force drives the beam toward the original, undeflected position upon release of the deflected end.

When the beam is released, the net restorative force displaces the beam toward the neutral, undeflected position. Furthermore, because the beam has momentum due to its mass, and no force halts the beam at the neutral position, the beam continues past the neutral position to an opposite, deflected position in which potential energy is once again stored in the deflected beam. Upon reaching the maximum deflection in the opposite direction, the beam reverses direction due to the stored potential energy in the deflected beam, and is moved again toward the neutral position. Again, the beam is not halted at the neutral position, and therefore the beam continues past the neutral position to a maximum deflected position very near the original deflected position. The beam continues cyclically to deflect to a maximum position, then reverse course and deflect to the opposite maximum position, and then reverse course again, at substantially consistent frequency and amplitude, until forces acting on the beam bring its oscillation to a halt. The consistent frequency of oscillation is the “natural frequency” of the beam, which is a function of the mass and the stiffness (spring constant) of the system.

In an example, a steel beam with a modulus of elasticity of 30×10⁶ lbs/in may have h=0.5 inches, b=3.0 inches and l=30 inches. If a load (M) of 35 lbs. deflects the free end of the beam about 0.34 inches, the beam elasticity then calculates to K=102.94 lbs/inch. If the load is instantly removed, the beam will oscillate with a frequency of 4.37 cycles/second, as calculated using the known equations shown in FIG. 1.

Similarly, a steel beam with h=1.5 inches, b=5.0 inches and l=30 inches may be deflected by a mass (load) of 13 lb. attached to the free end. This beam has a beam elasticity of 3125 lbs/inch and will oscillate at approximately 60 cycles per second with amplitude of 0.0042 inches.

As noted generally above, as the beam oscillates, it exhibits energy that flows cyclically between kinetic and potential. At initial deflection before release, all energy is potential. Upon release, the beam is displaced toward the neutral position as the stored potential energy causes movement and decreases as kinetic energy climbs. At the neutral position, which is the location of the beam at one-quarter of its cycle and maximum velocity, the energy resides in the kinetic energy of motion. At this momentary position, no energy is stored in deflection of the beam, because the beam is not deflected. The beam continues past the neutral position and, one quarter cycle later when the beam is at maximum negative deflection and velocity is 0, all of the energy resides in potential energy, and so on throughout the cycle. As shown in FIG. 3, the oscillation amplitude (X(t)) progressively decreases due to damping until the beam stops oscillating.

The total energy is the time average sum of the kinetic and potential energy for a complete cycle. To determine this, the common time average procedure of a quantity f(t) is used.

$$\begin{matrix}[ F ( t ) ] = \frac{1}{T} {\int }_{0}^{T} f ( t ) d t & where K = Coefficient of beam Elasticity \\ {U}_{k} = \frac{1}{2} {KA}^{2} \frac{1}{T} {sin}^{2} f ( t ) & where A = amplitude \\ {U}_{k} = \frac{1}{4} {KA}^{2} & where {U}_{k} = kinetic energy \\ & where T = period of 1 cycle\end{matrix}$$

This is determined by evaluating the integral and finding its value to be T/2. A similar evaluation to potential energy gives:

$$\begin{matrix}[ F ( t ) ] = \frac{1}{T} {\int }_{0}^{T} f ( t ) d t \\ {U}_{p} = \frac{1}{2} {KA}^{2} \frac{1}{T} {cos}^{2} f ( t ) \\ {U}_{p} = \frac{1}{4} {KA}^{2}\end{matrix} where {U}_{p} = potential energy$$

The energy is shared equally between kinetic and potential. The total energy for 1 cycle is Uₖ+Uₚ=¼KA²+¼KA² and Uₜ=½KA² inch pounds, where Uₜ=total energy.

### BRIEF SUMMARY OF THE INVENTION

When the free end of a cantilevered beam is deflected and released, the beam oscillates. The frequency and amplitude of the oscillation are determined by the amount of deflection, the elasticity of the beam and the mass of the system. Furthermore, due to damping (e.g., internal molecular friction, air resistance and possibly other influences), the amplitude of oscillation progressively decreases as illustrated in FIG. 3 and the beam comes to rest. A method and apparatus are contemplated that apply a driving force to the beam that has the same frequency of the beam oscillation. This force supplies sufficient energy to replace the losses due to damping, thereby allowing the beam to continuously oscillate. Beam amplitude can also be controlled by this driving signal.

### BRIEF DESCRIPTION OF THE SEVERAL VIEWS OF THE DRAWINGS

FIG. 1 is a schematic illustration of a beam (from the top and side views) showing how a force, such as a mass, M, deflects the beam from a neutral position. The equations in FIG. 1 are conventional.

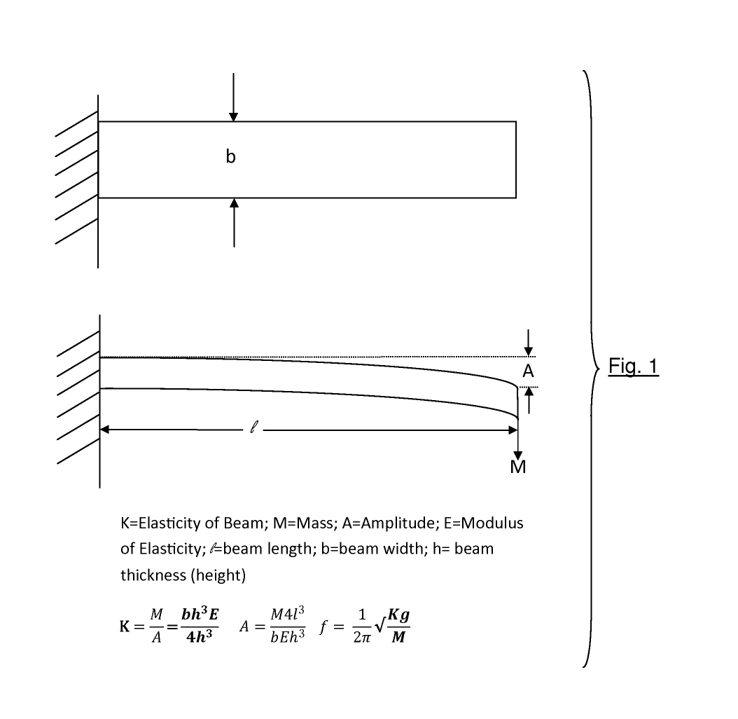

FIG. 2 is a schematic illustration of a beam embodying at least a portion of the present invention.

FIG. 3 is a conventional graph showing how damping reduces the amplitude X as a function of time.

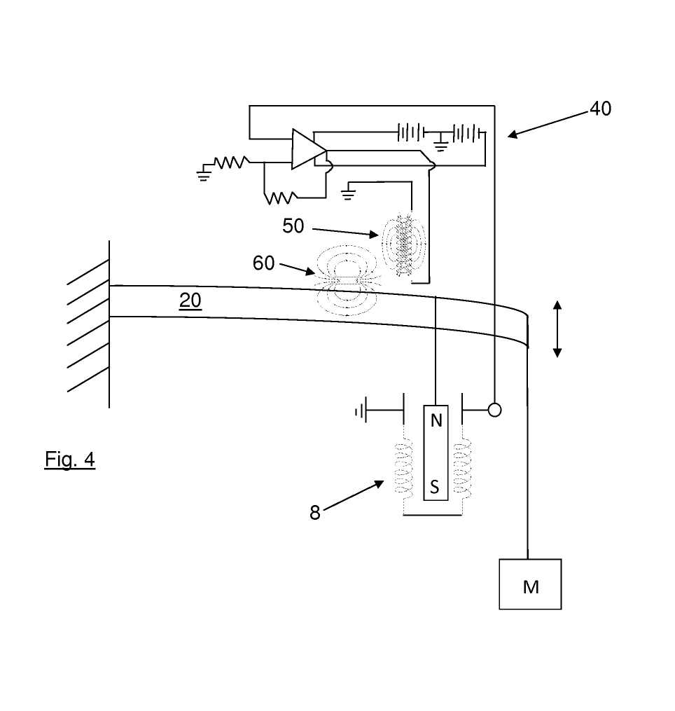

FIG. 4 is a schematic illustration of an embodiment of the invention.

FIG. 5 is a schematic illustration of an alternative embodiment of the invention.

In describing the preferred embodiment of the invention which is illustrated in the drawings, specific terminology will be resorted to for the sake of clarity. However, it is not intended that the invention be limited to the specific term so selected and it is to be understood that each specific term includes all technical equivalents which operate in a similar manner to accomplish a similar purpose. For example, the word connected or terms similar thereto are often used. They are not limited to direct connection, but include connection through other elements where such connection is recognized as being equivalent by those skilled in the art. In addition, a circuit is illustrated which is of a type which performs well known operations on electronic signals. Those skilled in the art will recognize that there are many, and in the future may be additional, alternative circuits which are recognized as equivalent because they provide the same operations on the signals.

### DETAILED DESCRIPTION OF THE INVENTION

Provisional U.S. Patent application Ser. No. 61/862,662 filed Aug. 6, 2013 is hereby incorporated in this application by reference.

The driven, continuously oscillating beam described herein can be used for many purposes, including but not limited to pumping of fluids, experimentation, and novelty products. An aluminum beam is used in one embodiment, and has a modulus of elasticity=10×10⁶ lbs/inch and dimensions of h=0.63 inches, b=1.25 inches and l=36 inches. The beam's frequency of oscillation is 1.83 cycles per second with amplitude of 3 inches. Of course, beams of other materials and sizes can be used, including but not limited to steel and other suitable metals, plastics, fiber-reinforced plastics, and any other suitable materials.

To accomplish continuous oscillation, the beam must be continuously driven to replace the energy lost to damping. A driving force must be synchronized with the beam's natural frequency of oscillation. Otherwise, the driving force will, at times, be in opposition to the beam's movement. Such non-synchronized, and especially opposition, forces will reduce the efficiency of the system and are undesirable.

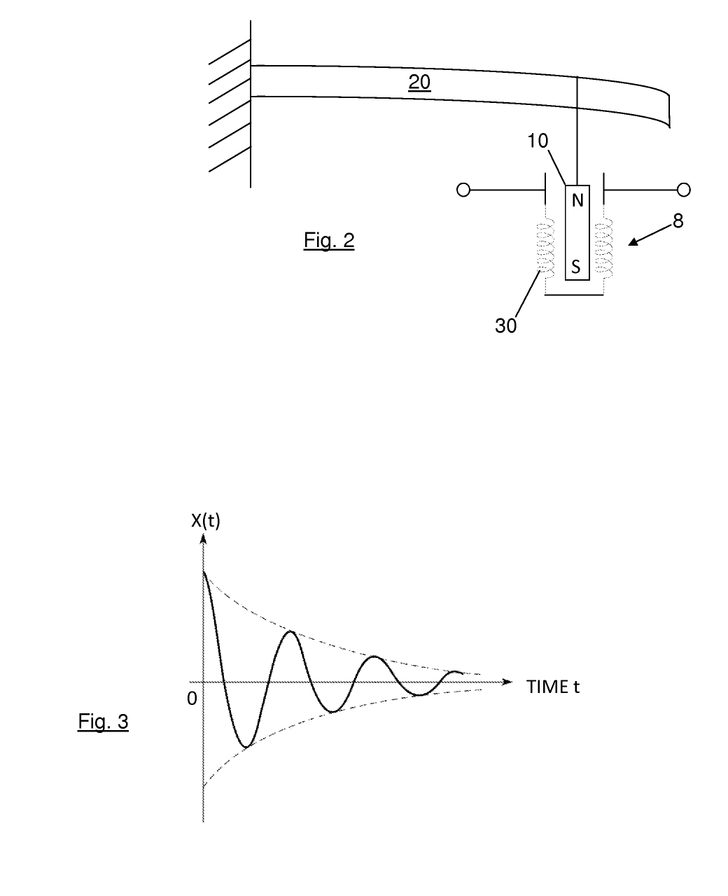

To achieve a signal corresponding with the frequency of the beam, the beam's mechanical motion is converted to an electrical signal. Referring to FIG. 2, a signal is created by a velocity transducer 8, which includes a permanent, preferably bar magnet 10 that is rigidly attached to the beam 20. The bar magnet 10 is disposed adjacent a solenoid type coil 30 so that the motion of the beam 20 generates a voltage in the coil 30 due to the time-changing magnetic field across the coil 30. The velocity transducer 8 generates a voltage signal that is proportional to the velocity of the beam 20. When the velocity (voltage) is at the peak, the beam is at its neutral position. When the velocity (voltage) is 0, the beam is at one extreme position of deflection or the opposite. The voltage is thus an accurate representation of the velocity and position of the beam in the beam's path of travel.

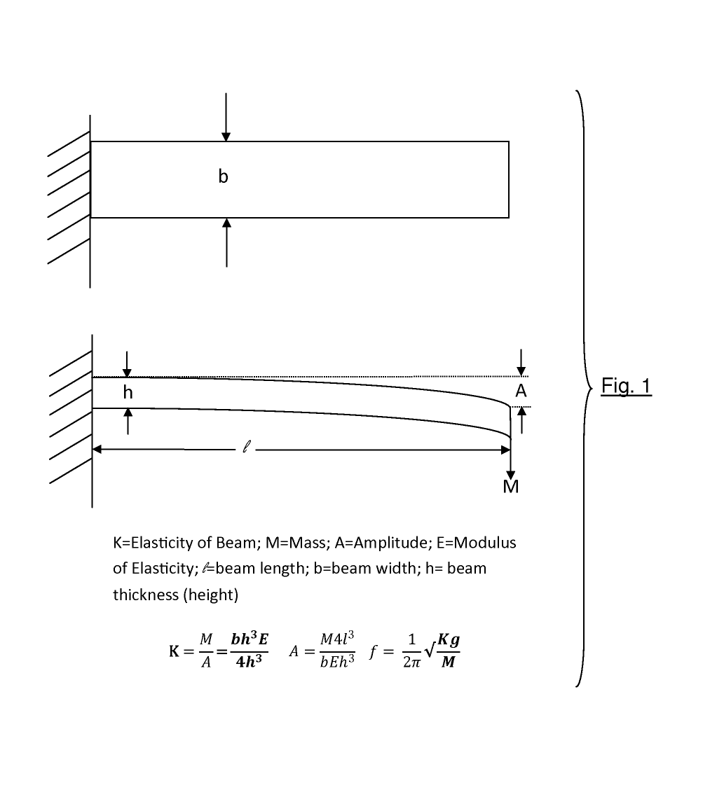

Referring to FIG. 4, the signal generated by the velocity transducer 8 is amplified and conditioned with a non-inverting operational amplifier 40 so the output signal contains the power necessary to drive the beam as described below. The amplified and conditioned signal is transmitted to an electromagnet 50 in close proximity to the beam 20. A permanent, preferably bar magnet 60 is attached to the beam 20 so the magnetic field of the magnet 60 interacts in a complementary fashion with the sinusoidal field of the electromagnet 50 as described below. Thus, the magnet 60 acquires the necessary energy to drive the beam 20 and help the beam achieve continuous oscillation despite damping. Of course, the magnet 60 can be replaced by a ferromagnetic material, or if the entire or most of the beam is ferromagnetic, the magnet 60 is the portion of the beam over which the electromagnet 50 has effect.

The voltage signal is generated by the velocity transducer 8 and then conditioned and amplified by the amplifier 40. After amplification and possibly conditioning, the voltage signal is sent to the electromagnet 50 that is positioned near the magnet 60. The electromagnet 50 is thus powered by a voltage signal that relates directly in magnitude and phase to the velocity of the beam 20. When the beam is momentarily stationary at both extremes, there is no time-changing magnetic field through the coils of the velocity transducer 8, and, therefore, the velocity transducer 8 sends a signal that is momentarily equal to 0. As the beam begins to move toward the neutral position from the extreme, the permanent magnet in the velocity transducer 8 begins to move, and therefore the magnetic field moves relative to the coils of the velocity transducer 8. As the beam increases in speed, the magnetic field increases in speed relative to the coils. Thus, an increasing voltage signal is generated by the velocity transducer 8. As the voltage signal increases from zero, the amplified voltage sent to the electromagnet 50 creates an increasing current through the coils thereof. This creates an increasing magnetic field. Because the position of the electromagnet 50 relative to the pole of the magnet 60 is established during calibration in order to drive the beam 20 as desired, the increase in magnetic field of the electromagnet 50 will increase the force driving the permanent magnet 60, and, thereby, the beam 20.

Once the beam 20 reaches the neutral position, it is moving most rapidly, and the time-changing magnetic field of the velocity transducer 8 is at a maximum. Thus, the voltage sent to the electromagnet 50 is at a maximum, and therefore the driving force applied to the beam is at a maximum. As the beam moves away from the neutral position, the velocity begins to slow, and thus the voltage and driving force are reduced. This occurs cyclically, and the amplifier 40 can be tuned to ensure that only the minimum amount of driving force is added to the system in order to maintain consistent amplitude oscillation. Of course, if a load is added to the system, as in the case of a pump, the amplification will have to compensate for the increased damping in order to maintain amplitude. Nevertheless, because the beam 20 can be designed in order to have mass suited to the particular purpose of the system, it is desired that amplification energy will be minimized.

Preferably, the electromagnet is positioned at the side of the beam 20, and the permanent magnet 60 is also mounted to the side of the beam 20, in order that the permanent magnet 60 is equidistant from the electromagnet 50 when the beam 20 is at an extreme. Alternatively, the electromagnet 50 can be positioned strategically closer to one extreme end of the beam's path so that the electromagnet's magnetic field has maximum effect at a desired point of the beam's cycle. Alternatively, there could be some compromise and the electromagnet can be positioned somewhere between the neutral point and an extreme.

It has been observed that positioning the electromagnet 50 over the opposite pole of the magnet 60 from the preferred pole halted all oscillation. Surprisingly, the beam reacted by resonating at an apparently much higher frequency than its resonant frequency and smaller amplitude than during typical operation. It is theorized that when the opposing magnetic fields of the magnet 60 and the electromagnet 50 rapidly influenced one another, it created a shock to the beam. This could be considered similar to striking a tuning fork with a mallet, causing the fork to resonate. The resonance at much higher frequency and smaller amplitude continued until the electromagnet was moved away from the opposite pole. The energy resulting from this phenomenon, as well as that from the beam's oscillation, will find many uses.

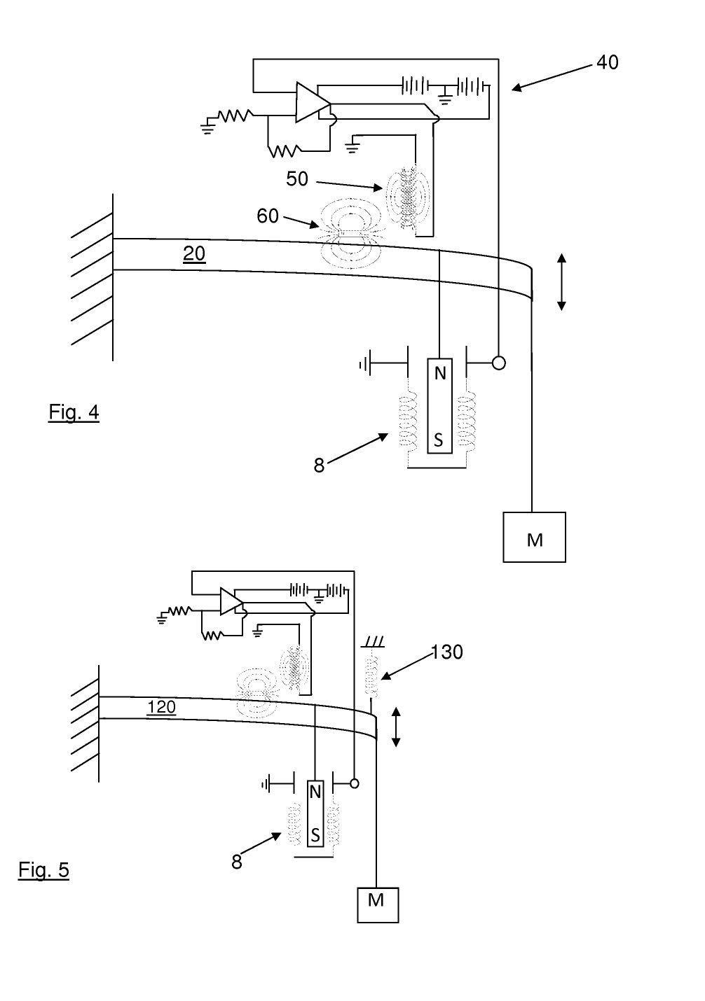

An alternative embodiment of the invention is shown in FIG. 5 to include a spring or other bias mounted to the beam. The reason for the bias is to counteract the effects of gravity or any other force that tends to pre-bend the beam downward (in the illustrations of FIGS. 2, 4 and 5). This bias is applied in the opposite direction of the natural gravitational force tending to pre-bend the beam as illustrated in FIG. 5. The beam 120 tends to be pre-bent at least by the force of gravity acting on the beam and the mass, M. In a contemplated embodiment, the mass, M, can be one or more sections of pipe used in an oil well pump. A bias, such as the coil spring 130, is mounted at one end to the beam 120 and the opposite end to a stable support, such as ground. The spring 130 is pre-loaded when attached to the beam 120 so that the spring 130 applies an upwardly-directed force to the beam 120 to partially or completely counteract the deflection of the beam 120 due to the force of gravity. Beam operation is the same as described above after making an adjustment of the system coefficient of elasticity.

This detailed description in connection with the drawings is intended principally as a description of the presently preferred embodiments of the invention, and is not intended to represent the only form in which the present invention may be constructed or utilized. The description sets forth the designs, functions, means, and methods of implementing the invention in connection with the illustrated embodiments. It is to be understood, however, that the same or equivalent functions and features may be accomplished by different embodiments that are also intended to be encompassed within the spirit and scope of the invention and that various modifications may be adopted without departing from the invention or scope of the following claims.

1. A system for oscillating continuously comprising:
(a) a cantilevered beam having a first beam end mounted to a stable support and an opposite, second beam end free to move relative to the support;
(b) a velocity transducer mounted near the second beam end for detecting a velocity of the beam and thereby producing a signal that is a function of the velocity; and
(c) a beam driver mounted adjacent the beam for receiving the signal from the velocity transducer and applying a force to the beam in accordance with the received signal.

2. The system in accordance with claim 1, wherein the velocity transducer further comprises a magnet mounted to one of the beam and the velocity transducer and coil mounted to another of the beam and the velocity transducer.

3. The system in accordance with claim 1, wherein the beam driver further comprises an amplifier for amplifying the signal to create a voltage that is a function of beam velocity, a first magnet connected rigidly to the beam and an electromagnet positioned adjacent and spaced from the first magnet, wherein the voltage is applied to the electromagnet which thereby drives the magnet and the connected beam as a function of the voltage.

4. A system for continuously oscillating a cantilevered beam having a first beam end mounted to a stable support and an opposite, second beam end free to move relative to the support, the system comprising:
(a) a first magnet mounted to one of the beam and the support and a conductive coil mounted to another of the beam and the support and configured to detect a velocity of oscillation of the beam and produce an electronic signal that is a function of the velocity; and
(b) an electronic circuit that receives the electronic signal and at least amplifies the electronic signal to produce a voltage that is a function of the velocity of the beam;
(c) a second magnet rigidly mounted to the beam;
(d) an electromagnet mounted adjacent the second magnet, the electromagnet configured to receive the voltage and produce a magnetic field that is a function of the voltage, whereby the electromagnet applies a force to the second magnet that is a function of the received voltage.

5. The system in accordance with claim 4, wherein the second magnet is a permanent magnet.

6. A method of driving a cantilevered beam, the method comprising:
(a) creating a voltage signal that is a function of a velocity of oscillation the beam, wherein the voltage signal is also substantially in phase with the velocity of oscillation of the beam;
(b) receiving the voltage signal in an amplifier circuit and amplifying the voltage signal to produce an amplified voltage;
(c) receiving the amplified voltage in an electromagnet that is disposed near the beam, a function of the amplified voltage, thereby applying an in-phase force to a first magnet mounted to the beam in close proximity to the electromagnet.
